(19) United States
(12) Patent Application Publication
(10) Pub. No.: US 2005/0077509 A1
(43) Pub. Date: Apr. 14, 2005

(54) Size regulating systems

(76) Inventor: Erez Yahalomi, Ramat Hasharon (IL)

Correspondence Address: Erez Yahalomi, Tarpad 8, Ramat Hasharon, 47250, IL

(21) Appl. No.: 10/686,914

(22) Filed: Oct. 14, 2003

(30) Foreign Application Priority Data
Oct. 31, 2002 (IL) 152565

(51) Int. Cl. H01L 31/0328

(52) U.S. Cl. 257/14; 257/25

(57) ABSTRACT

A system for regulating the particles distribution energy dependent parameter. The particles may have a cell containing the particles, a sensor to detect the particles distribution, a source to regulate the particles distribution energy dependent parameter. The particles may be electrons or a group of particles such as molecules.

### FIELD OF INVENTION

The present invention relate to a novel switching device for computing and electronics.

### BACKGROUND OF THE INVENTION

Devices for electronic switching are well known in the art various applications. Several alternate principles are usually utilizes for the purpose of producing electronic switching. One method is MOSFET. It consist of a P type semiconductor with two n type regions one of either end, on the top surface above the P-type region, is a thin layer of oxide insulator, on the surface of this insulator there is a metallic contact. By applying a positive voltage to the central electrode the positive charge on the gate electrode (p/region) repels the holes at the top surface of the p-type layer. Thermally created conducting electrons in the p-type will be attracted by positive charge. This means, electrons can flow freely from one side to the other and the device is on. If the voltage is removed there is no current and the device is off. Another method is the bipolar transistor a bipolar can be an n-p-n or p-n-p structure. It is critical that the middle layer (base) be thin (<<1 micron) for high current gain bipolar. Bipolar have restricted current flow. A bipolar transistor can be operated in different regimes that are determent by the biases of the two junctions, the most important regimes is the active (normal) mode where the emitter-base junction is forward and the collector—base junction is reverse. In the saturation mode the collector current Ic is a weak function of Ib or Ie. If the cut off mode set by Ib or Ie equals zero the transistor is off and Ie is close to zero. Bipolar transistors are more suitable for high speed circuits because of their high transconductance. Another advantage of the bipolar transistor is that the threshold for turn off is less sensitive to process variation.

### SUMMARY OF THE INVENTION

It is an object of the present invention to provide a method and a device for switching in computing, electronics, optoelectronics or any kind of circuit. Wherein the switching state is relate to the particle wave function size in space.

Another object of the present invention is to provide a method of changing the particle wavefuntion size by the energy received or transmitted by the particle.

According to further feature of the present invention changing the particle wave function size and the device switching state can be regulate through kinetic energy, photonic energy, potential energy for example coulomb potential energy, photonic energy or phonon energy.

Another object of the present invention is to provide a method for detection of the switched state comprising: two boundaries in two sides of the switching particle. Wherein the two switching states is detected by the corresponding values of the potential between the two boundaries. According to a further feature of the present invention another method for detection of the switched state comprising boundaries with neutral part at the height of the particle wave function in the first state is (a) a second boundary part above the first part that is charged and is corresponding to the height of the second particle state. The particle state is detected by the charge potential value between the two boundaries at the second part. According to a further of the present invention another method for detection of the switched state. Wherein the two switching states is detected by photon detection.

Another object of the present invention is to provide a switching device for switching between two states such as 1 or 0 in computing or on off state. Wherein the switched state depends on the particle wave function dynamic size change in space Another object of the present invention is to provide a switching device comprising: (a) two conductive planes; (b) an electron which can be switched between two state where in one state the particle move to a region between the two plane and the in second state the particle is moving outside the region between the two planes, wherein the movement is translation movement of the all the particle. (c) the two state are detected by the difference in the charge potential between the two planes. The term particle can refer to a group of more than one particle. That have a referred function as a referred particle in claim 1-25.

### BRIEF DESCRIPTION OF THE DRAWINGS

The invention is herein described, by way of example only, with reference to the accompanying drawings, wherein.

FIG. 1a is a schematic representation of a switching device based on particle wavefunction size change. Wherein the particle wave function is in its initial size.

FIG. 1b is a schematic representation of a switching device based on particle wavefunction size change, the particle increase its energy and its wavefunction size.

FIG. 2a is a schematic representation of a switching device; the device is switched to the second state by kinetic energy gain from other particle.

FIG. 2b is a schematic representation of a switching device; the device is switched back to the first state by transferring kinetic energy to other particle.

FIG. 3a is a schematic representation of a switching device wherein the switching is based on photon absorbsion.

FIG. 3b is a schematic representation of the device and particle state after it absorbed the photons.

FIG. 4a is a schematic representation of a switching device, wherein the switching to a larger particle wavefunction state is based on energy gain from phonons.

FIG. 4b the particle decrease it size and change the device state by transferring energy to phonons.

FIG. 5 is a schematic representation of a switching device based on particle wavefunction size change wherein the switching is based on potential energy interaction.

FIG. 6a is a schematic representation of a switching device, wherein the particle wave function is not large enough to fill the detection zone.

FIG. 6b is a schematic representation of a switching device, wherein the particle wave function fill the detection zone.

FIG. 7 is a schematic representation of a switching device, wherein the detection of the switching state is based on photons detection.

FIG. 8a is a schematic representation of a switching device. Wherein the particle size static and the current is zero.

FIG. 8b is a schematic representation of a switching device wherein the particle size change is dynamic producing a charge current.

FIG. 9a is a schematic representation of a switching device in accordance with another embodiment of the invention. Wherein the particle is outside the detection zone.

FIG. 9b is a schematic representation of the switching device wherein the particle is inside the detection zone.

FIG. 10 is a schematic representation of a switching device in accordance with another embodiment wherein the particle wave function influences current.

FIG. 11a is a schematic representation of a switching device wherein the particle is in smaller range in the cavity due to repulsive potential.

FIG. 11b is a schematic representation of a switching device wherein the particle is in larger range in the cavity.

FIG. 12a is a schematic representation of a switching device in accordance with another embodiment wherein the particle wave function is in smaller range.

FIG. 12b is a schematic representation of the switching device wherein the particle wave function is in larger range.

### DETAILED DESCRIPTION OF THE PREFERRED EMBODIMENTS

The present invention is of novel switching devices suitable for example to computing, electronics, optoelectonics, optics or communication. These devices are characterized by fast switching time, low energy consumption and small size. The principles of the present invention may be better understood with reference to the drawings and the accompanying description.

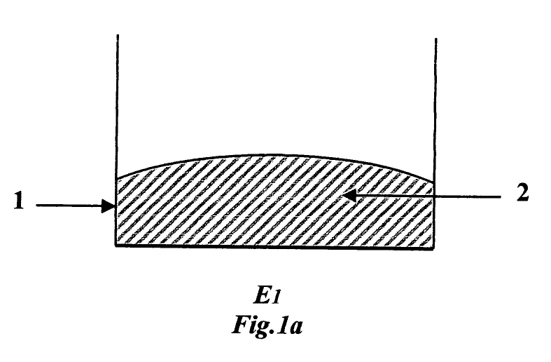

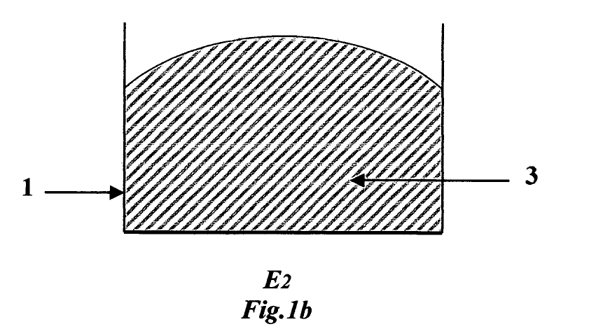

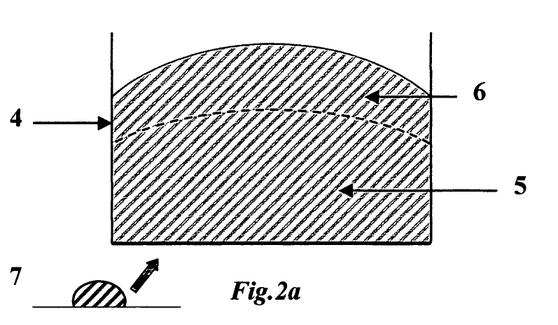

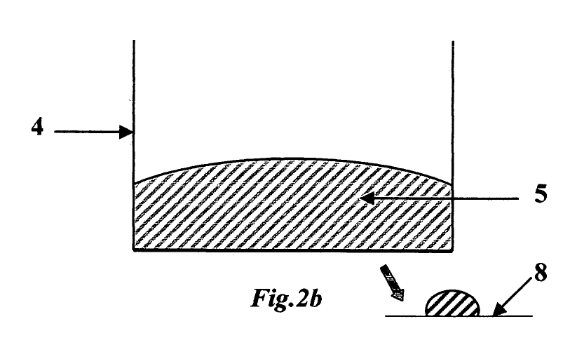

With reference to FIG. 1 there is seen a switching device based on changes of the particles wave functions size inside a cavity space, the notation cavity is referred in general to any kind of zone which contained most of the particle wave function. The notation particle can refer to several kind of particle for example; electron, proton, neutron, molecule or photon, the notation particle refer to one or more than one particle that have refereed function as described for the denoted particle. Changes in the particle wave function size derived from changes in the particle energy increasing the particle energy increases the particle wave function size in the cavity and the particle is switched from state 1 to state 2. Decreasing the particle energy to its initial value results in reverting the particle wave function size to its initial size and to state 1. In FIG. 1a, there is shown a cavity 1 for example a quantum well. Inside the cavity there is a particle wave function 2. The particle have an energy denoted by E₁ this particle wave function occupied certain space in the cavity which indicated as state 1. In FIG. 2a the particle has energy E₂ where E₂>E₁ this caused the particle wavefunction 3 inside the cavity 1 to be larger indicating switching state 2.

With reference to FIG. 2 there is shown a device for switching between two states wherein the states depends on the particle wave function size. A change in the particle energy caused the change in particle wave function size. The change can be in the particle kinetic energy or the particle potential energy or the particle total energy. In FIG. 2a Particle wave function is increased in cavity 4 from its initial size 5 due to kinetic energy receipt from an interaction with an additional particle 7. The device is switched from its initial state characterized by wave function size 5 to a second state 6 characterized by a larger wave function size inside the cavity.

With reference to FIG. 2b there is shown how kinetic energy is transferred from the particle in cavity 4 to an additional particle 8 which interacted with the particle in the cavity. This cause reduction in the particle wave function to its initial size 5 and the device is switched back to state 1.

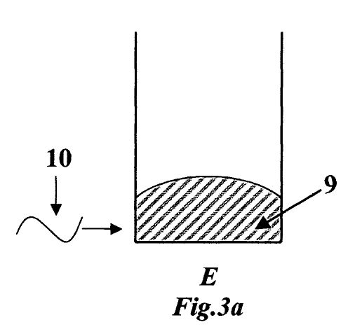

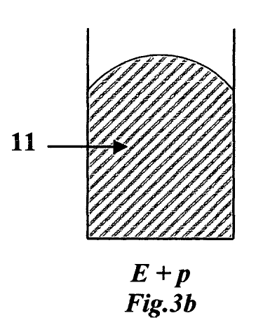

With reference to FIG. 3 there is shown a device for switching between two states where the states depends on the particle wave function size. Wherein the switching between the two states is achieved by photon absorbsion or transmission by the switched particle. In FIG. 3a a particle 9 with initial energy E absorbed a photon 10 transmitted to the particle 9 by an additional source. It is shown in FIG. 3b the particle energy is increase to an energy of E+p where p denoted the energy due to the photon absorbsion. The increase in the particle energy cause an increase in the particle wave function size 11. This change in the particle wave function size represent a switching in the device state. A reverse switching between the two states can be achieved by photon emission by the switched particle 11 or by an interaction with an additional particle or phonon which reduced the switched particle to its initial size and state.

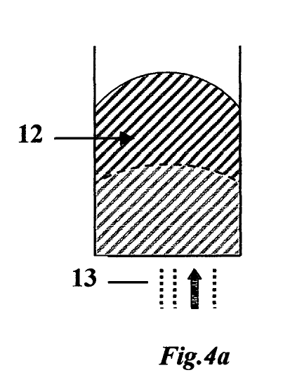

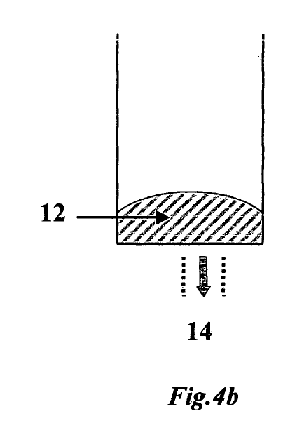

With reference to FIG. 4 there is shown a device for switching between two states where the states depends on the particle wave function size. Wherein the switching between the two states is achieved by phonon or phonons energy exchange with the switched particle. FIG. 4a show an increase in the switching particle in the cavity 12 wavefunction size due to an energy gain from an interaction with a phonon 13, which transfers energy to the switched particle. The particle wave function gain is regarded as a switching to the second state of the switching device. FIG. 4b show the device reverted to its initial state by an energy transmitted from the particle 12 to an interacting phonon or phonons 14. This caused the particle wave function to decrease to its initial size and the device is switched back to its initial state.

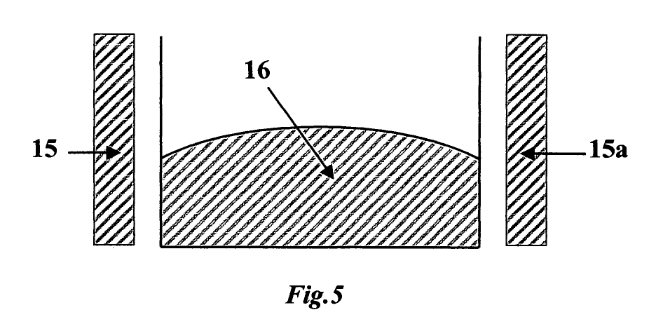

With reference to FIG. 5 there is shown a device for switching between two states where the states depends on the particle wave function size. Wherein the switching between the two states is achieved by potential energy interaction. FIG. 5 shows a switching device, comprising two charged zones 15,15a in two sides of the of the switching particle 16. The charged zones 15,15a are used for detection of the device states by the potential value between the two zone. This potential is different when the particle wave function 16 in the cavity has smaller or bigger size which corresponding to state one or two of the device respectively.

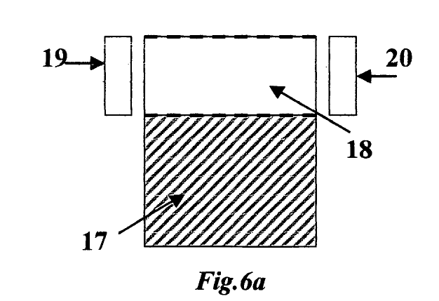

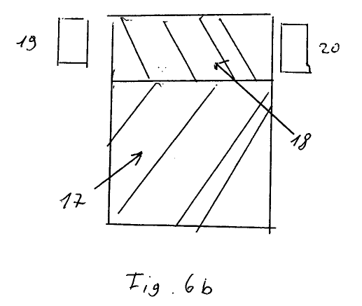

With reference to FIG. 6 there is shown a device for switching between two states comprising a cavity divided into two parts the lower part 17 is at the height of the particle wave function at its initial size. The second part 18 is above the first part is at the height of the particle wave function at its larger size corresponding to the second state of the device. On two sides of the second part there are two charged areas 19,20 creating an electric potential between them, the two zones are for detection of a particle wavefunction presence in the second part of the cavity 18. When the particle wave function is only in the first part of the cavity 17 the potential between the two zones 19, 20 has one value When the particle wave function is in its larger state filling the second part 18 as well, the potential between the two zones 19,20 have a second value. The potential values is depends on the charge in the two zones, when the particle wave function fill in the second part of the cavity 18 it can increase the potential between the two zones or it can decrease it for example by screening effect, depending on the charge in the two zones.

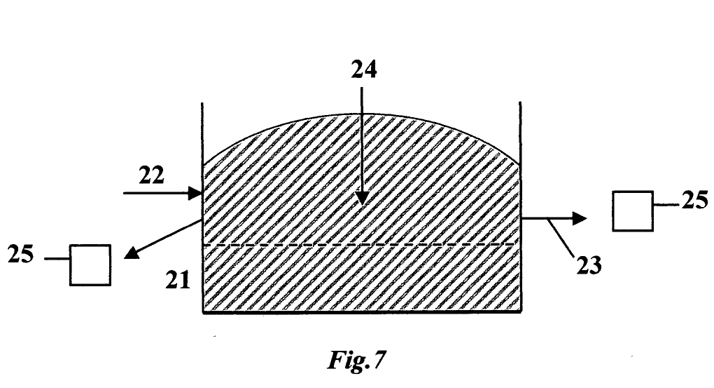

With reference to FIG. 7 there is shown a device for switching between the two states depended on the particle wave function size. The device states is detected by photons wherein the detection is based on photon scattering 21, photon absorbsion 22 or photon transmission 23 of the particle wave function 24. The detector 25 can be in different places near the cavity depending if the detection derived from scattering, absorbsion or transmission.

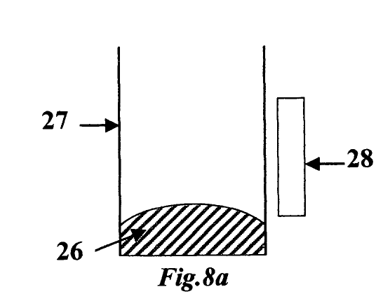

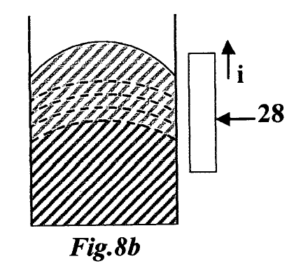

With reference to FIG. 8 there is shown a device for switching between two states. Wherein the switched state depends on the particle wave function dynamic size change in space. The increasing or decreasing process of the particle wave function cause a charge current This charge current is denoted as one state in the device. The other state is when there is no charge current in the device cavity. FIG. 8a shows a particle wave function 26 inside a cavity 27, the wave function size is not changed this is related to device state with zero charge current. FIG. 8b shows a dynamic increasing of the particle wave function 26 due to energy gain by the particle this dynamic increase result a charge current i detected by element 28.

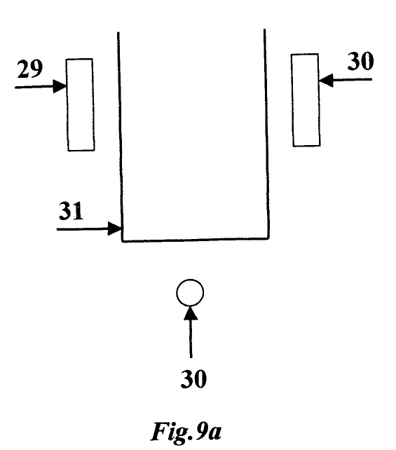

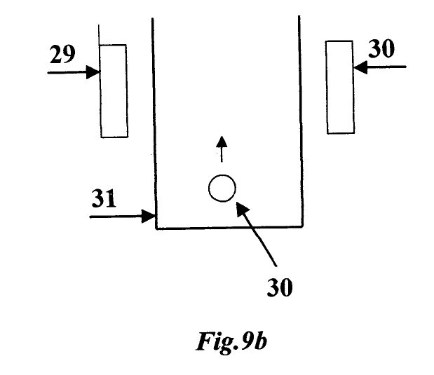

FIG. 9 shows a switching device for switching between two states such as 1 or 0 in computing or on off states comprising: two conductive planes 29,30 a cavity between them 31, a particle 32 which can be switched between two states. Wherein one states the particle 32 move to a region between the two planes 29,30. In the second state the particle is moving outside the region between the two planes 29,30. In this embodiment the movement is translation movement of the all the particle and not wave function expansion as in the previous embodiments. The two states are detected by the difference in the charge potential v₁, v₂ values between the two planes for the two states.

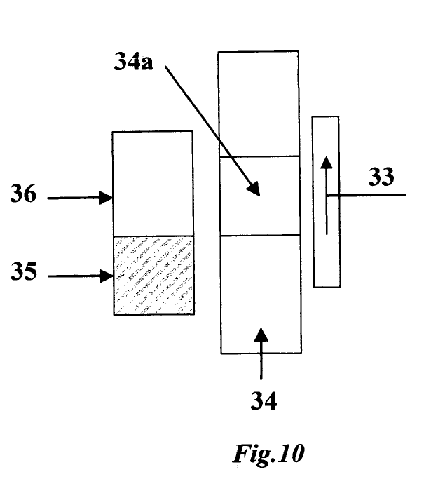

FIG. 10 shows a device for switching between two states wherein the states ate defined by a charge current value, influenced by a particle Which can be switched between two sizes. The device comprise charge current element 33, an element 34 with a limited region 34a, wherein the particle wave function in this region can influenced the charge current of element 33 which located near element 34. Outside this region of element 34 the charge is screened. A particle near element 34 where element 33 is on the other side or a particle inside element 34, can be in two states. In the first state 35 the wave function size of the particle is not large enough to be in the limited region of element 34. In the second state 36 the particle wavefunction is large enough to be in the limited region of element 34 as well, thereby influencing the charge current value in element 33. The device two states are determined by the charge current value in element 33. Each of the two charge current values represented a different device state. The switching between the two particle wave function sizes is achieved due to particle energy change and can be realized by any of the methods described in the description chapter.

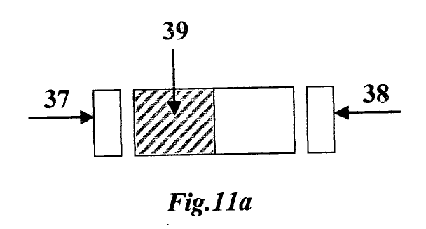

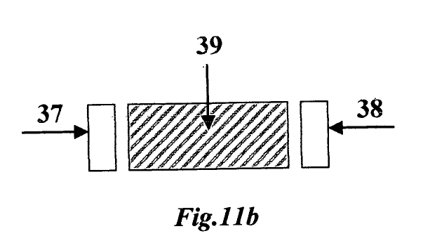

FIG. 11 shows a device for switching between two states comprising two regions which create a repulsive potential on a particle between them. The particle size is depends on the repulsive potential value the larger is the repulsive potential value the smaller become the particle wave function size, this method of changing the wave function size is different from the method described so far and it is based on repulsive forces from the two charge planes towards the particle cavity. By reducing the repulsive potential value the particle wave function size expands, thus achieving two states denoted by two particle wave function sizes. To revert to the initial state the repulsive potentials are revert to its initial value and the particle wave function decreased to its initial size. Referring to FIG. 11a the repulsive potentials of element 37,38 are directed toward the particle wave function 39 in the cavity which reduces the wave function size. Referring to FIG. 11b the potential is reduced due to the repulsive potentials of element 37,38 and the particle wave function 39 is expanded corresponding to the second state of the device. The two switched states in this device can be realized by charge current value. By changing the repulsive potential value the particle wave function size expands or decreased and an electric current is obtained in the process. The switching states are denoted by an on current state and an off current state.

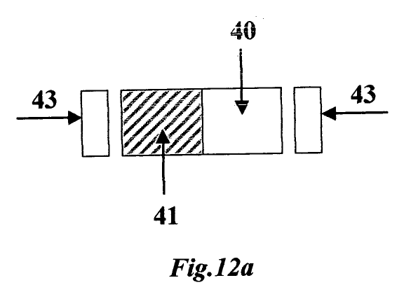

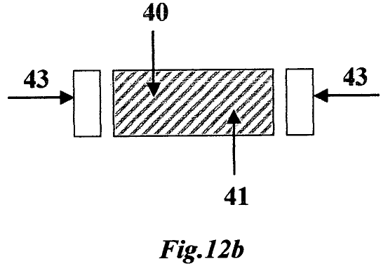

FIG. 12 shows a device for switching between two states where the switching is made in two cavity 40,41 regions of the same height. In FIG. 12a State one is denoted by a particle wave function in a limited region in the cavity 41. In FIG. 12b State two is denoted by a particle wave function in a wider region in the cavity 42. Wherein the detection method 43 are any of the method described in this description chapter but they positioned in a way to detect the particle wave function fill, in the region that is not filled in the smaller wave function state. The method for the particle energy change can be any of the method described in the description section.

1. A switching device for switching between two states in computing or on off states,
wherein the switched state depends on the particle wave function size in space and
wherein the wave function size depends on the particle total energy and the switching between the device two states is done by changing the particle total energy.

2. A switching device as in claim 1 wherein one of the states is indicated by a certain particle wave function size and the other state is indicated by a bigger particle wave function size.

3. A switching device as in claim 2 wherein the wave function size is referred to the uncertainly distribution in space of the particle wave function.

4. (canceled)

5. (canceled)

6. A switching device as in claim 1 wherein the wave function size depends on the particle kinetic energy and the switching between the device two states is done by changing the particle kinetic energy.

7. A switching device as in claim 1 wherein the switching between the device two states is done by changing the particle potential energy.

8. A switching device as in claim 1 wherein the switching between the two states is achieved by transmitting energy to or from an additional particle and the particle representing the device switching state.

9. (canceled)

10. A switching device as in claim 1 wherein the switching between the two states is achieved by photon or absorption or emission by the switched particle.

11. (canceled)

12. (canceled)

13. A switching device as in claim 1 wherein the switching between the two states is achieved by phonon or phonons energy exchange with the switched particle.

14. A switching device as in claim 1 wherein the switching between the two sizes of the particle wave function is achieved by a potential energy interaction.

15. (canceled)

16. A switching device as in claim 1 comprising two boundaries on two sides of the switching particle in the second state wherein the two switching states are detected by the corresponding values of the potential between the two boundaries.

17. (canceled)

18. (canceled)

19. A switching device as in claim 1 wherein the two particle states are detected by photon detection.

20. A switching device as in claim 19 wherein the photon detection is based on photon scattering, photon absorption or photon transmission.

21. A switching device according to claim 1 wherein the change in state is detected by a corresponding charge current.

22. (canceled)

23. (canceled)

24. A switching device as in claim 1 wherein the term particle refers to one or mare than one electrons neutrons or protons.

25. (canceled)

26. (canceled)

27. (canceled)

28. A switching device as in claim 1 comprising two regions which create a repulsive potential on a particle between them wherein tithe particle size is dependent on the repulsive potential value such that by reducing the repulsive potential value the particle wave function size expands, thus achieving two states denoted by the particle wave function sizes and to revert to the initial state the repulsive potential is reverted to its initial value.

29. (canceled)

30. A switching device as in claim 1 wherein the change in sate is detected by a corresponding change in voltage on an electrode.

31. A device comprising:
a container in which at least one particle is contained, wherein the particle in a first lower energy state is confined to a given region and wherein, in a second higher energy state, the particle is increased in size such that a portion of the at least one panicle is outside the given region, while remaining in the container; and
at least one electrode adapted to detect the presence of the portion of the at least one particle outside the region or of the transition of the at least one particle from the first to the second state.

32. A device according to claim 31 wherein the at least one electrode is positioned such that a detectable current is caused to flow in an electrode when the energy state chances.

33. A device according to claim 31 wherein the at least one electrode is positioned such that a detectable voltage change is induced on an electrode when said state changes.

34. A device according to claim 31 wherein the given region is bounded by a second region into which the particle expands in said second state.

35. A device according to claim 34 wherein the second region comprises a second container, such that in the second state the particle fills the second region.

36. A device according to claim 31 wherein the particle is an electron.

37. A method of switching comprising:
providing at least one particle having a wave function bound to a region;
switching the at least one particle from a first lower energy state in which the wave function of at least one particle has a first, small extent to a second higher energy state in which the wave function of the at least one particle has a second larger extent, while remaining bound to the region; and
determining the state of the at least one particle or the transition of the at least one particle from one of said states to the other.

38. A method according to claim 37 wherein the determination of the state includes detection of a voltage induced by the expansion of the wave function of the at least one particle.

39. A method according to claim 37 wherein the determination of the state includes detection of a current induced by expansion of the wave function of the at least one particle.

40. A method according to claim 37 wherein said switching is effected by a change in one or both of the potential or kinetic energy of the particle.

41. A method according to claim 37 wherein said switching is effected by an energy exchange with another particle or a phonon or by absorption or emission of a photon.
